(19) United States
(12) Patent Application Publication
(10) Pub. No.: US 2026/0173314 A1
(43) Pub. Date: Jun. 18, 2026

(54) SYSTEM AND METHOD FOR CONTROLLING COOLING OF COMPUTING SYSTEM

(71) Applicant: Amazon Technologies, Inc., Seattle, WA (US)

(72) Inventors: Paul H Mazurkiewicz, Lake Forest Park, WA (US); Damian Philip Evans, Bellevue, WA (US)

(21) Appl. No.: 18/979,015

(22) Filed: Dec. 12, 2024

(51) Int. Cl. H05K 7/20; G06F 1/20

(52) U.S. Cl. CPC H05K 7/20281; G06F 1/206

(57) ABSTRACT

A cooling system is configured to generate dynamic coolant flow paths for a computing device using a trained model. The cooling system can include a trained machine learning model configured to generate and update a thermal map based on changing operating conditions of the computing device. The thermal map can indicate thermal variations across the computing device. Further, a cooling controller can generate coolant circulation characteristics based on the thermal map or an updated thermal map received from the trained machine learning model. The coolant circulation characteristics minimizes or reduces the thermal variations across the computing device. A cooling device can be coupled to the computing device and configured to create coolant flow across the computing device based on the coolant circulation characteristics.

### BACKGROUND

Computing systems can be subject to many factors that may impact performance. Many relevant factors can relate to mechanical aspects of the components that are utilized in computing systems. Some mechanical considerations can relate to dissipation of heat that may be generated from one or more chips, a set of dice (which may include one die or more than one dice or dies), or other heat-generating components in use. Other considerations can include size limitations. Even minor changes to accommodate and balance among such considerations may render cost savings and/or operational performance benefits that may be significant or non-negligible, especially when implemented across large scale production volumes typical with manufacture of components for computing systems.

### BRIEF DESCRIPTION OF THE DRAWINGS

Various embodiments in accordance with the present disclosure will be described with reference to the drawings, in which:

FIG. 1 is block diagram of a system including a cooling system and a computing device in accordance with various embodiments;

FIG. 2 illustrates training of a machine learning model in accordance with various embodiments;

FIG. 3 illustrates a system that may include ferrofluid for defining guides of flow paths within a coolant chamber in accordance with various embodiments;

FIG. 4 illustrates a perspective view of the system of FIG. 3 implemented relative to other components, such as within a computing system, in accordance with various embodiments;

FIG. 5 illustrates a series of thermal images representing examples of heat distributions that may be addressed by the system of FIG. 3 in accordance with various embodiments;

FIG. 6 illustrates a series of fixed anchors that can be implemented in the system of FIG. 3 in accordance with various embodiments; and

FIG. 7 is a flow chart depicting a process that may be performed with respect to a coolant system of FIGS. 1 and 3 in accordance with various embodiments.

### DETAILED DESCRIPTION

Embodiments herein relate to computing systems and cooling systems used to cool the computing systems. A cooling system herein can provide a control mechanism that combines computational fluid dynamics (CFD) and machine learning algorithms to optimize cooling for a computing system. For example, optimization of cooling can include efficient distribution of coolant flow over a computing system and/or one or more silicon dies (e.g., a processor or other integrated circuit board) based on temperature variations across a surface of the computing system or its components. This control mechanism ensures efficient thermal management for high-performance computing applications or other computing applications.

In various embodiments, a computing system, also referred to as a computing device, includes components that generate heat during operation. This can create a heat distribution with substantial temperature variations between different portions of the computing system. Additionally, a heat distribution across the computing system can change over time due to changing operating conditions or modes, and/or environmental factors. The present disclosure provides a cooling system employing a machine learning model to improve cooling efficiencies of the computing system. This in turn improves operating efficiency or maximum operating efficiency of the computing system. The machine learning model can account for variations in temperature across the computing system and assist with planning coolant flow layouts or paths across the computing system.

The machine learning model can be pre-trained to predict temperature variations (e.g., represented as thermal maps) based on changing operating conditions of a computing device. In some embodiments, the machine learning model can be trained to generate thermal maps based on various factors such as operating modes, operating duration of time, changes in environmental conditions, temperature information from thermo-couples of a processor, processing state information from the processor, or other information. Based on the thermal maps, coolant flow path layouts can be tailored or adjusted to reduce variations in the temperature across the computing device.

A cooling device can be coupled to the computing device and implement the tailored coolant flow path layouts. The cooling device can include components that can vary coolant flow paths, as specified by the tailored coolant flow path layouts. For example, in some embodiments, the cooling device can include a cooling plate having a coolant chamber and ferrofluid. Coolant flow paths within the coolant chamber can be modified by channels that are constructed by the ferrofluid. The ferrofluid materials can be acted upon by magnetic fields to adjust an arrangement of the ferrofluid materials in order to change a flow path of conduits, channels, or other guides for controlling fluid flow characteristics through the coolant chamber in use. Accordingly, coolant flow paths may be adjusted by adjusting the magnetic field to change ferrofluid placement and/or arrangement within the chamber.

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

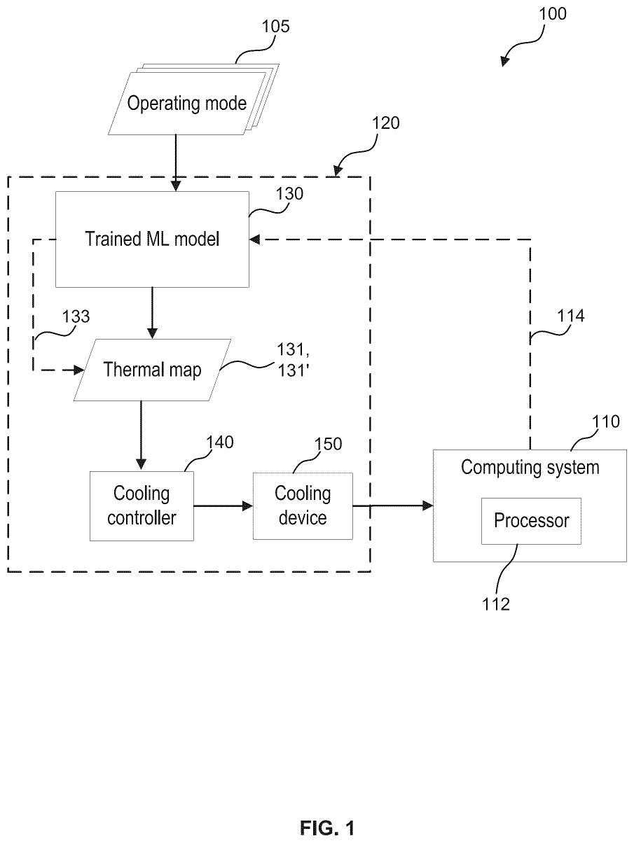

FIG. 1 is a block diagram of a system 100 including a computing system 110 coupled to a cooling system 120, in accordance with various embodiments. The cooling system 120 can be configured to cool the computing system 110 based on thermal variations caused during operation of the computing system 110. For example, the thermal variations can be caused due to different operating modes, operating duration, one or more processes executed on the computing system 110, changes in environmental conditions or other factors. The cooling system 120 can be configured to generate dynamically changing coolant flow paths to reduce dynamically changing thermal variations across the computing system 110.

In some embodiments, the computing system 110 or sensors monitoring the computing system 110 can periodically or continuously provide real-time information 114 associated with computing processes causing temperature variations to the cooling system 120. In some embodiments the real-time information 114 can be provided by the computing system 110 or sensors within the computing system 110. For example, the information 114 can include, but is not limited to, temperatures at different locations of a processor, number of processes or tasks being executed, processing states, computing load, processing speed, memory usage, or other computing information. In some embodiments, the real-time information 114 can be provided by sensors (e.g., thermal imaging sensors, or other environmental sensors) positioned away from the computing system 110. Based on the information 114, the cooling system 120 can predict thermal variations across the computing system 120. The predicted thermal variations can be further used to determine and/or update the coolant flow paths to provide efficient cooling of the cooling system 110.

The computing system 110 can include one or more processors 112 and supporting computing components (omitted for simplicity and brevity). For example, the supporting components can be, but are not limited to, electrical components, electronic components, and mechanical components. The supporting components may be coupled (e.g., electrically connected or communicably connected) to the processors 112. Each of the processors 112, when performing various computing processes, can generate heat within the computing system 110. In operation, one or more of the processors 112 can communicate with each other to cooperatively perform computing tasks. For example, one or more of the processors 112 can be configured to perform various processes, for example, serving up a webpage, searching information in a database, compressing or decompressing a file, processing an image, extracting data from a database, or other processes. Depending on the processes being executed on a processor 112, there can be variations in computing load, duration of execution of the processes, or other computing related factors. These variations can affect different physical locations (e.g., associated with memory, RAM, etc.) of the processor 112 variations in temperatures across the processor 112 and/or other locations of the computing system 110. Furthermore, the processor 112 can transmit electrical or wireless signal between different components, which can cause further temperature variations e.g., at connection points, and/or locations of the different components. The computing system 110 can be or include, but is not limited to, a die, a motherboard, a server, a graphic card, a power systems or others, the components of which are well known and omitted here for brevity. To account for the temperature variations experienced by the computing system 110 and/or the processor 112, the present disclosure provides a machine learning driven cooling system (e.g., 120).

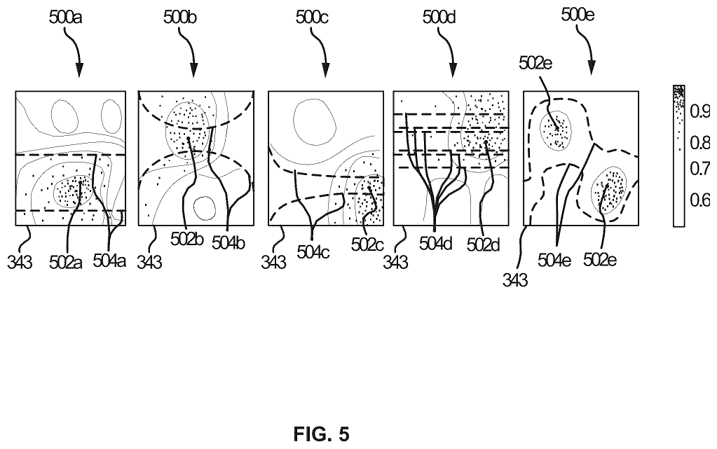

Although the concepts herein are discussed primarily referring to the processor 112, as a heat-generating component, it should be understood that could be other types of heat-generating components having variable heat profiles, including but not limited to the examples referenced herein (e.g., when discussing FIG. 5). In some embodiments, the computing system 110 may include chip-on-wafer-on-substrate (CoWoS) and system on chips (e.g., with chiplet architectures). These CoWoS can have stacked dies which can have different heat profiles compared to other processors, and may benefit from cooling of a silicone substrate as well. In some embodiments, a system on chip may include a processor surrounded by a plurality of memories accessible by the processor. The processor and memories can have different thermal profiles based on the processing at the processor and how memories are being accessed. Accordingly, cooling patterns can include different locations of the processor as well as different locations of the memories and/or other associated components.

In various embodiments, the cooling system 120 can include a trained machine learning model 130 configured to generate and update thermal maps 131 associated with the computing system 110. The cooling system 120 can include a cooling controller 140 configured to determine or plan for coolant flow paths such that temperature variations in the model-generated thermal maps 131 can be reduced or minimized. The thermal maps and associated coolant flow paths can change dynamically across the computing system 110. The cooling system 120 can further include the cooling device 150 coupled to the computing system 110. The cooling device 150 can be adaptable to implement the dynamically changing coolant flow paths generated by the cooling controller 140, thereby providing improved cooling of the computing system 110 e.g., compared to a fixed path cooling of a computing system.

In various embodiments, the trained machine learning model 130 can be a pre-trained model associated with the computing system 110. The trained model 130 can be configured to predict thermal variations based on changing operating conditions associated with the computing system 110. These thermal variations can be represented as a thermal map 131. In various embodiments, the trained model 130 can account for changes in operating conditions via model inputs (e.g., operating mode, time, temperature data, etc.) associated with the computing system 110. In the illustrated embodiment, the changes in the operating conditions can be characterized by operating modes 105 of the computing system 110. In some embodiments, an operating mode 105 can be associated with a number of processes or tasks being executed that can create different processing states, varying computing load, varying processing speed, memory usage, or other computing information. Depending on the operating mode 105, the computer system 110 can experience thermal variations over time. The trained model 130 can be pre-trained based on the information related to the operating modes to predict these temperature variations.

In various embodiments, the trained model 130 can be configured to generate a thermal map 131 indicating thermal variations across the computing system 110 and/or the processor 112. For example, the thermal map 131 can identify a plurality of heat zones having different temperatures across the computing system 110 and/or the processor 112. The plurality of heat zones can include a first heat zone having a higher temperature than a second heat zone. The plurality of heat zone can include two, three, four, or more heat zones, and is not limited to a particular number of zones. In some embodiments, the first heat zone can be characterized by a first range of temperature, and the second heat zone can be characterized by a second range of temperature higher than the first range of temperature. In some embodiments, the first heat zone can be associated with a first location of the computing system 110 or a first location of the processor 112. Similarly, the second heat zone can be associated with a second location of the computing system 110 or a second location of the processor 112. Non-limiting examples of thermal maps are illustrated in FIG. 5 and discussed in detail later in the disclosure.

In various embodiments, the trained machine learning model 130 can be further configured to generate an updated thermal map 131′. In some embodiments, trained machine learning model 130 can generate the updated thermal map 131′ based on updated inputs such as the operating mode 105 and a processing time in the operating mode 105, and/or temperature related data obtained from the processor 112. One or more updated thermal maps 131′ can be generated on a periodic basis or continuously. Depending on a difference between a prior thermal map and an updated thermal map, cooling characteristics of the computing device 110 may be adjusted. For example, if the difference between two thermal maps is above a specified threshold (e.g., percentage or difference value of temperatures), a coolant flow path across the computing system 110 may be adjusted. Otherwise, the coolant flow path may be maintained or not adjusted.

In some embodiments, the trained machine learning model 130 can receive temperature related data 114 from the computing system 110. For example, the temperature related data can include, but is not limited to at least one of: temperature values obtained from thermo-couples within the processor 112, or processor states information stored within a memory of the processor 112. The temperature related data 114 can be received periodically or continuously. Based on the temperature related data 114, the trained machine learning model 130 can generate an updated thermal map 131′. In some embodiments, real-time temperature data can be obtained from sensors within the processor 112 and/or the computer system 110. In some embodiments, real-time temperature data can be obtained from sensors (e.g., thermal imaging camera) located remotely or away (e.g., above or below) from the processor 112 and adapted to monitor temperature variations across a surface of the processor 112 and/or the computer system 110. In some embodiments, the trained model 130 may be configured to continue to learn, e.g., to leverage real-time customer data to more accurately predict the thermal maps 131′.

The trained model 130 is not limited to a particular type of machine learning model or a particular training method or algorithm. The model can be convolutional neural network (CNN), k-NN, linear regression, naive Bayes, neural networks, logistic regression, perceptrons, support vectors Machine (SVM), Relevance Vector Machine (RVM), deep learning models, Neural operator model, and/or other trainable machine learning models.

In various embodiments, the cooling system 120 can include the cooling controller 140 configured to generate coolant circulation characteristics based on the thermal map 131 received from the trained machine learning model 130. For example, the coolant circulation characteristics can include at least one of a coolant flow path, a coolant type, a coolant amount, a coolant flow rate, or other adjustable coolant parameters. In some embodiments, the coolant circulation characteristics along the computing device 150 can be based on minimizing or reducing the thermal variations across the computing device 150. For example, the cooling controller 140 may employ fluid flow equations such Navier-Stokes equations, which govern the motion of fluids and provide basis for modeling the intricate flow dynamics of the fluid across a device. Using the fluid flow equations, the cooling controller 140 can simulate complex interactions between a coolant and intricate patterns of heat dissipation across a surface of the processor 112 and/or the computing system 110. Further, the cooling controller 140 can be configured to determine updated coolant circulation characteristics based on the updated thermal map 131′.

In various embodiments, the cooling controller 140 and the trained model 130 can be integrated or configured to work cooperatively. In various embodiments, the trained model 130 can be trained to identify hotspots (e.g., having temperatures above a specified temperature threshold) across a surface and correlate the hotspots with the simulated flow patterns from the cooling controller 140. In some embodiments, hotspots can represent a portion of the processor 112 that performs a very high amount of computing operations. The iterative process between the trained model 130 and the cooling controller 140 can allow the cooling system 120 to learn and evolve. The cooling system 120 can continuously improving its ability to predict optimal coolant paths tailored to thermal signatures (e.g., represented as the thermal maps 131, 131′) of each processor (e.g., 112) or silicon die. The cooling system 120 can ensure that the coolant flow can be strategically directed toward the areas (e.g., hotspots) requiring the most intensive cooling, maximizing the efficiency and effectiveness of the overall thermal management solution. The coolant flow paths can be implemented via a cooling device (e.g. 150) adapted to dynamically change coolant flow paths.

In various embodiments, the cooling device 150 can be coupled to the computing device 110 and configured to create coolant flow across the computing device 110 based on the coolant circulation characteristics. For example, the cooling device 150 can adjust or create a physical coolant flow path planned by the cooling controller 140, adjust a coolant amount, adjust a coolant flow rate, or other coolant parameters. Accordingly, the cooling device 150 can adapt to changing cooling needs of the processor 112 and/or the cooling system 110.

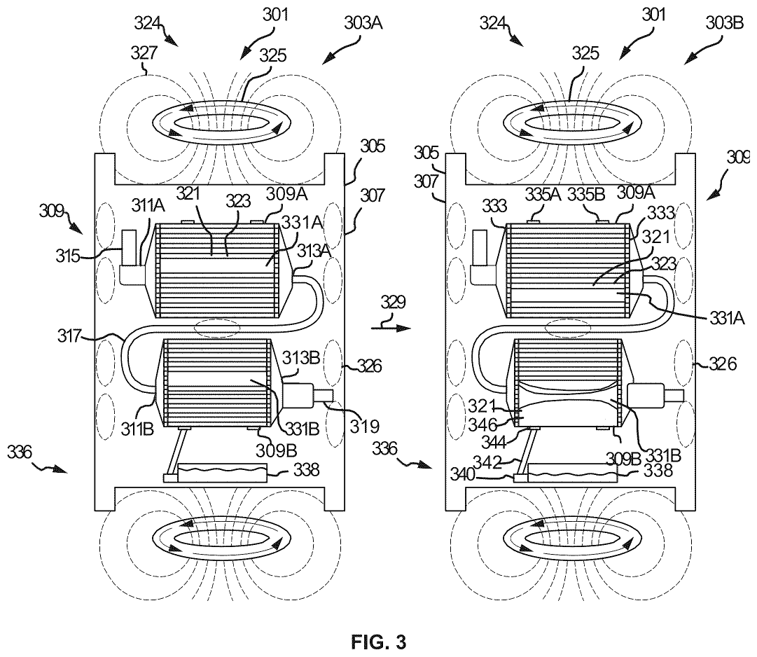

In some embodiments, the cooling device 150 can include ferrofluid configured to create or adjust coolant flow paths, which is further explained in detail with respect to FIGS. 3-6. As an example, the cooling device 150 can include a cooling plate (e.g., 305 in FIG. 3) formed on the computing device or couplable with the computing system 110 or the processor 112. The cooling plate (e.g., 305) can be positioned or coupled under or alongside the computing system 110 or the processor 112. An amount of ferrofluid (e.g., 321 in FIG. 3) may be configured to form rearrangeable set of walls (e.g., channel boundaries 504a and 504b in FIG. 5) based on the coolant circulation characteristics. For example, the coolant circulation characteristics can indicate arranging a coolant flow path along different zones of the plurality of heat zones so that a heat zone having a higher temperature can be cooled faster than other heat zones. A magnet set (e.g., magnetic field emitters 325 in FIG. 3) including one or more electromagnets may be coupled with the cooling plate (e.g., 305). The magnet set (e.g., magnetic field emitters 325) can be operated to alter placement of the ferrofluid to create the set of walls (e.g., channel boundaries 504a and 504b in FIG. 5). Furthermore, a set of fixed anchors (e.g., 602) may be fixed in a predetermined plan within the cooling plate (e.g., 305), and configured to receive the ferrofluid (e.g., 321) such that the fixed anchors (e.g., 602) and the ferrofluid (e.g., 321) together define coolant flow path boundaries within the cooling plate (e.g., 305).

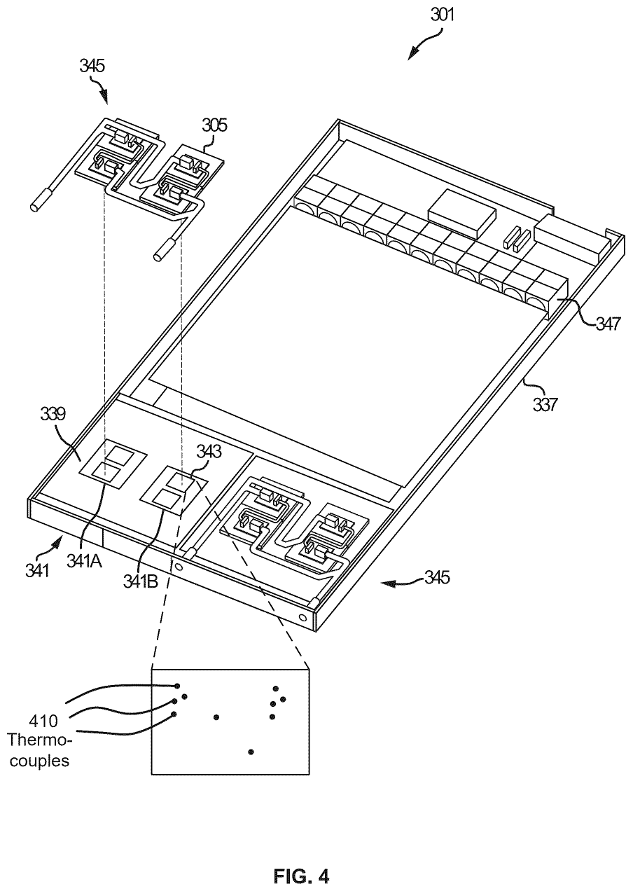

The present disclosure is not limited to a particular cooling device. Other cooling devices using air, liquid, or other coolants may be employed. Such cooling devices can include fluid flow channels (e.g., a network of connected conduits) and controllable valves (e.g., to control open/close of one or more conduits, control flow rates in the conduits, etc.) to adjust cooling flow characteristics (e.g., a coolant path, a flow rate, etc.). For example, the cooling device 150 can include a fan (e.g., 347 in FIG. 4) configured to direct an air flow and an amount of air over the computing device 110. The coolant circulation characteristics can include at least one of an air flow direction along different zones of the plurality of zones, or a fan speed to direct the amount of air along different zones of the plurality of zones. In some embodiments, the cooling device can include movable baffles to direct airflow along a specified path. For example, in some embodiments, the baffles can be angled to move air along a particular direction across the computing system. As another example, one or more baffles may be closed to block air flow so that a higher amount of airflow can be directed to remaining baffles, which may direct the air to certain portions of the computing system.

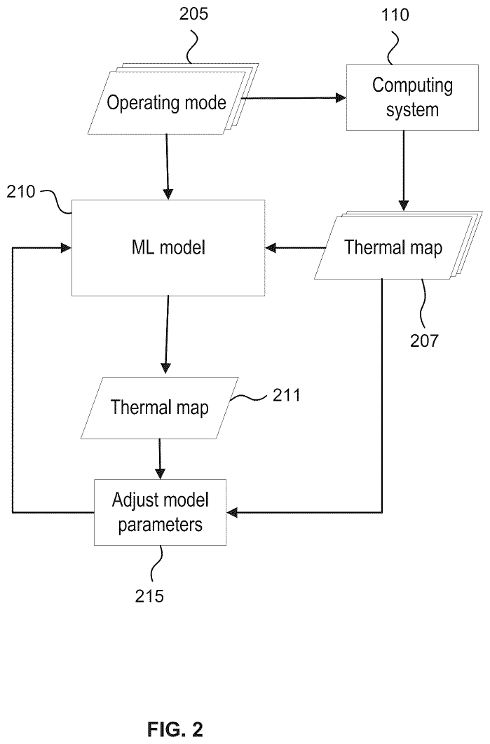

FIG. 2 illustrates an example training process of a machine learning model 210 in accordance with various embodiments. The machine learning model 210 may be trained using a training algorithm configured to identify patterns within input data and predict output values from a given set of input variables. For example, the input variables can be operating modes of a processor, temperature data of the processor or the environment, processor states, usage data associated different components coupled to the processor, or other factors discussed herein. In some embodiments, the model 210 can be trained using any of unsupervised or supervised machine learning algorithms. As one example, supervised learning involves a machine learning model that is trained from labeled training data. Each instance of the training data has a pair of input objects (represented as vectors) and desired output values (also called supervised signals). The supervised learning algorithm analyzes the training data and generates an inferred function that can be used to map new instances within an input data. In unsupervised training, a deep learning model can process unstructured data (e.g., text or images) with no labelling, and can automatically determine a set of features which distinguish different categories of data from one another. Hence, if the input data are dissimilar, and/or the training algorithms are different, the trained model will be dissimilar and unlikely to fail due to a common cause.

In some embodiments, the model 210 can be trained using training data including, but not limited to (i) one or more operating modes 205 of the computing system 110, and (ii) a plurality of thermal maps 207 associated with each of the operating modes 205 of the computing device. Alternatively or additionally, temperature data from thermo-couples (e.g., 410 in FIG. 4) on a processor. Using a training process or algorithm, the model 210 can be trained to generate a thermal map 211. The training process or algorithm can involve adjusting one or more model parameters to determine adjusted model parameters 215 based on a cost function. The adjusted model parameters 215 can be, but not limited to, weights of a neural network. In some embodiments, the cost function can be a function of differences between the model generated thermal maps 211 and the thermal maps 207 of the training data. The training algorithm can adjust the model parameters such to reduce or minimize differences between model generated thermal maps 211 and the plurality of thermal maps 207 of the training data. In some embodiments, a gradient decent method or other optimization methods may be used to minimize the cost function. Upon completion of the training process, the model 210 can be referred as a trained model (e.g., the trained model 130 in FIG. 1).

FIG. 3 illustrates two instances of a system 301 in differing configurations. For example, a first configuration 303A is shown at left in FIG. 3 and a second configuration 303B is shown at right in FIG. 3. The system 301 can be a non-limiting example of cooling device (e.g., 150 in FIG. 1) of an advanced cooling system (e.g., 100). The system 301 can be integrated with a cooling controller 140 (e.g., implementing fluid flow equations such as the Navier-Stokes equations, as explained with respect to FIG. 1) and a trained machine learning model (e.g., 130 in FIG. 1). The system 301, the cooling controller 140 and the trained machine learning model (e.g., 130) can work in tandem to periodically or continuously analyze thermal hotspots on a computing system (e.g., a silicon die, a processor 112) and generate optimal coolant flow patterns. The system 301 can be integrated with microprocessor-controlled magnets and ferrofluidic channels to create a dynamic and adaptable approach to optimizing a cooling flow. The magnet control functions associated with the magnets of the system 301 can be implemented on a dedicated microprocessor or the controller 140 itself, without limiting the scope of the present disclosure.

As will be explained in more detail below, ferrofluids may flow through a network of channels on a surface of a silicon die or a processor. For example, the network of channels can be etched and/or microscopic channels. These etched channels can allow flow of ferrofluid and/or coolant. For example, within the etched channel a ferrofluid may be used to block a channel to direct the coolant through unblocked channels. Alternatively, a network of channels can be embedded within a cooling device itself. In some embodiments, magnets may be strategically placed within the system 301 and controlled by the microprocessor configured to receive coolant flow paths from the controller 140. The microprocessor or the controller 140 can be configured manipulate a magnetic field surrounding these channels, effectively reshaping and redirecting the flow of the ferrofluids in real-time. The microprocessor or the controller 140 can act as a controller configured to receive feedback (e.g., thermal maps 131, 131′) from the trained machine learning model (e.g., 130) and dynamically adjust the magnetic field patterns to adapt the ferrofluidic channels. As the thermal hotspots on the computing system (e.g., associated with silicon die or the processor 112) shift or evolve due to changing computational loads or environmental conditions, the trained model (e.g., 130) can analyze the data and provide updated thermal maps to plan optimal flow patterns. The flow patterns can be sent to the microprocessor or the controller 140. In response, the microprocessor or the controller 140 can be configured to precisely modulate the magnetic fields, causing the ferrofluids to reconfigure their flow paths, effectively channeling the coolant to the areas identified (e.g., in thermal maps 131, 131′) as needing the most intensive cooling. This symbiotic relationship between the fluid flow equations (e.g., in the controller 140), the trained machine learning model (e.g., 130), ferrofluids, and controlled magnets creates a highly responsive and intelligent cooling system. This way, coolant flow reaches the hottest parts of the computing system but also dynamically adapts to changing thermal conditions, providing a level of thermal management superior to fixed channel approaches, for example.

The system 301 can include a cooling plate 305. The cooling plate 305 can be configured for dissipating heat, for example. The cooling plate 305 can include a body 307. The body 307 may be formed of aluminum or other suitable material with appropriate characteristics for functions described herein. For example, the cooling plate 305 may be constructed of material with suitable heat transfer characteristics, material that may be sufficiently robust for loadbearing, and/or material that may be suitable for machining to provide a suitable structure for purposes described herein.

The body 307 can include at least one chamber 309. In FIG. 3, examples of the chamber 309 are individually identified as a first chamber 309A and a second chamber 309B. Although two chambers 309 are shown in FIG. 3, any suitable number of chambers 309 can be utilized. Any chamber 309 may be a coolant chamber, for example.

The coolant chamber 309 can define a coolant inlet 311 and a coolant outlet 313. Examples of the coolant inlet 311 and the coolant outlet 313 are denoted with respective suffixes in FIG. 3, such as a first coolant inlet 311A, a second coolant inlet 311B, a first coolant outlet 313A, and a second coolant outlet 313B. Any coolant inlet 311 may be coupled with a suitable input for receiving water or other coolant, for example. The coolant inlet 311 may be coupled with an inlet fitting 315. The inlet fitting 315 may provide a suitable interface for enabling flow from a coolant supply (such as a water supply) and into the coolant inlet 311. In the embodiment shown in FIG. 3, the inlet fitting 315 is shown coupled with the first coolant inlet 311A of the first chamber 309A, while the first coolant outlet 313A is coupled with a hose 317 that provides fluid flow from the first chamber 309A into the second chamber 309B. In the depicted example, the hose 317 is shown providing fluid flow from the first coolant outlet 313A of the first chamber 309A and carrying flow to the second coolant inlet 311B of the second chamber 309B. Fluid can flow through the second chamber 309B in the depicted embodiment to the second coolant outlet 313B, which is also shown coupled with an outlet fitting 319.

More generally, the inlet fitting 315 and the outlet fitting 319 may be coupled to a single chamber 309 in operation or at differing ends of a series of chambers 309, which may be connected by the hose 317 or any other suitable structure to permit flow of coolant through the system 301. For example, although the hose 317 is depicted as a flexible tube, the hose 317 may additionally or alternatively correspond to or be replaced with a channel or other conduit structure that may be machined, coupled, or otherwise incorporated into and/or with the cooling plate 305. Moreover, although the cooling plate 305 is depicted as rectangular in shape in FIG. 3, any other suitable shape may be utilized.

The chamber 309 may be supplied with an amount, quantity, or mass of ferrofluid 321. The ferrofluid 321 may be utilized to define one or more guides 323. The guides 323 may guide coolant flow within the chamber 309 in use. For example, the guides 323 may direct coolant flow movement between the coolant inlet 311 and the coolant outlet 313 of a respective chamber 309.

The ferrofluid 321 may correspond to any suitable magnetic material suspended in a carrier substance fluid, such as a liquid. Water-based or oil-based solutions may be utilized. A water-based carrier substance for the ferrofluid 321 may be most suitable for situations in which a coolant utilized is not also water-based. Since water-based coolant (e.g., plain water or water with additives for biocide, anti-corrosion, or other purposes) may be prevalent to implement (e.g., due to simplicity and/or ready availability of materials), oil-based carrier substances (e.g., rather than water-based) may be implemented in many embodiments. In various embodiments, the ferrofluid 321 may include an oil or carrier substance that is hydrophobic. Including a hydrophobic carrier substance may facilitate a distinct separation between the ferrofluid 321 and water (or other coolant) in the system. In some embodiments, a water-based ferrofluid 321 may be utilized with an oil-based coolant. More generally, materials may be selected so that a base substance of coolant and a carrier substance of a ferrofluid will be immiscible, which may allow the ferrofluid 321 and the coolant to maintain distinct separation in use. A distinct separation may facilitate the ferrofluid 321 acting as a guide for the coolant without mixing with the coolant, for example.

Examples of magnetic particles that may be included in the ferrofluid 321 may include ferromagnetic particles or ferrimagnetic particles. Some examples of substances that may be suitable for particles in the ferrofluid 321 may include pure forms, alloys, or compounds of iron, cobalt, nickel, and certain rare-earth metals. Overall, the “ferro” prefix in ferrofluid 321 need not necessarily necessitate that ferrous or iron particles be present in the ferrofluid but may refer to the ferrofluid 321 exhibiting ferromagnetic and/or ferrimagnetic behavior and/or properties (e.g., regardless of whether or not ferrous or iron materials are included). The particles may be nanoparticles (e.g., which may remain suspended within the carrier substance), whereas particles of a micrometer scale (e.g., which may be suitable for use in a magnetorheological fluid) may settle over time.

In some examples, the carrier substance can further include oleic acid, tetramethylammonium hydroxide, citric acid, soy lecithin, or other suitable surfactant, which may contribute to preventing magnetic particles from adhering together into heavier clusters that could precipitate out of the ferrofluid solution.

Generally, the ferrofluid 321 may be responsive to magnetic fields to change arrangements of the ferrofluid 321. For example, in response to one magnetic field, the ferrofluid 321 may align magnetic particles of the ferrofluid 321 to a first arrangement or configuration. Then, in response to a change of field, the ferrofluid 321 may align magnetic particles of the ferrofluid 321 to a second arrangement or configuration.

The system 301 may further include or be implemented relative to a set 324 of one or more magnetic field emitters 325. Each magnetic field emitter 325 may correspond to a structure suitable for or capable of emitting magnetic fields 327. The magnetic field emitter 325 may be controllable to alter a magnetic field 327 supplied. Some examples may include an electromagnetic that can be controlled to alter a supplied magnetic field 327. In some embodiments, one or more permanent magnets (e.g., movable or static) may be utilized and/or supplemented with electromagnets. Any other form of electromagnet, permanent magnets, or other form of magnetic field emitters can be utilized.

Magnetic field emitters 325 herein may correspond to magnets. Magnets may correspond to any structure capable of providing a magnetic field 327. The magnetic field emitters 325 may alter magnetic fields 327 which may extend into and/or through the chamber 309. For example, the magnetic field emitters 325 may be positioned relative to the body 307 so as to be operable to alter placement and/or arrangement of the ferrofluid 321 in the chamber 309.

In some embodiments, different magnetic fields 327 from different magnetic field emitters 325 in the set 324 may interact with one another (such as to provide constructive or destructive interference and/or other modulation of magnetic fields 327) to control arrangement of the ferrofluid 321 along particular locations, lines, and/or paths within the chamber 309. Although two magnetic field emitters 325 remote from and at opposite sides of the cooling plate 305 are shown in solid lines in FIG. 3, any number and/or positioning on and/or adjacent cooling plate 305 may be utilized. Some examples of alternate locations 326 that may include magnetic field emitters 325 are depicted by dashed line ovals in FIG. 3 (which may include on differing sides of a given chamber 309, laterally offset from a given chamber 309, vertical offset from a given chamber 309, and/or between multiple chambers 309), although any combination of suitable numbers and/or positioning of magnetic field emitters 325 can be included.

Altering the arrangement of the ferrofluid 321 within the chamber 309 may adjust a physical characteristic of at least one of the guides 323 within the chamber 309. Examples of physical characteristics may be location, shape, and/or size. As one example, as depicted in FIG. 3, as the magnetic field emitters 325 transition from a first operational state to a second operational state (such as depicted by arrow 329 and corresponding to shifting from the first configuration 303A shown at left in FIG. 3 to the second configuration 303B shown at right in FIG. 3), the guides 323 may shift the location of a first channel 331A bounded by the guides 323 defined by the ferrofluid 321. This may correspond to relocating a first channel 331A in the first chamber 309A within or among other channels formed by the ferrofluid 321. For example, the first channel 331A may move from a location (e.g., shown in the first configuration 303A) in which three other channels are one side and four other channels are on another side and may move to a different location (e.g., shown in the second configuration 303B) in which six other channels are on one side and one other channel is on another side. The other channels may provide respectively smaller flow paths than the first channel 331A, for example.

Other examples of changes in physical characteristics are shown with respect to a second channel 331B. The second channel 331B may be changed in shape in addition to being changed in location. For example, the guides 323 may be straight (e.g., as shown for the second channel 331B in the first configuration 303A) or curved (e.g., as shown for the second channel 331B in the second configuration 303B) or may be adjusted to exhibit any other suitable geometry (which may include, but is not limited to, at least partially straight, at least partially non-straight, diverging, or converging). In some embodiments, utilizing curved guides 323 can provide a nozzle effect to accelerate speed of coolant flowing through a restriction of the nozzle relative to parts of the chamber 309 at which restriction of the nozzle is not present.

The size of the second channel 331B is also shown as being altered with the shape and location, although any one of shape, location, or size may be altered independently. A change in size may correspond to a maximum dimension, a minimum dimension, or other comparable reference dimension that may be compared between different configurations. For example, a largest dimension (e.g., along opposite ends) is shown smaller for the second channel 331B in the first configuration 303A than in the second configuration 303B, and the smallest dimension (e.g., in a middle portion) is shown larger for the second channel 331B in the first configuration 303A than in the second configuration 303B.

In some examples, a magnetic field 327 from the magnetic field emitter 325 may be sufficient to maintain ferrofluid 321 within the chamber 309 notwithstanding flow of coolant through the chamber 309. The chamber 309 may include one or more barriers 333 which may be positioned to contain ferrofluid 321 within the chamber 309 independent of a presence of a magnetic field 327 (such as if the magnetic field emitters 325 are shut off or cease providing a predictable magnetic field 327 in use). The barriers 333 may correspond to membranes or other structures with apertures or orifices that are sized to be large enough to allow molecules of water or other coolant to pass through and small enough to prevent particles of the ferrofluid 321 from passing through. More generally, the barriers 333 may be arranged to prevent passage of the ferrofluid 321 through the coolant outlet 313 and/or the coolant inlet 311 of a given chamber 309.

In some aspects, sizing and/or positioning of channels 331 in the second chamber 309B may be modulated to account for heat absorbed in the first chamber 309A prior to reaching the second chamber 309B. For example, a wider second channel 331B may be utilized in the second chamber 309B than a first channel 331A utilized in the first chamber 309A.

Also shown in FIG. 3 are an introduction port 335A and an escape port 335B. For example, the ferrofluid 321 may be introduced so as to be received within the chamber 309 through the introduction port 335A. Air may escape through the escape port 335B in response to receiving the ferrofluid 321 through the introduction port 335A. Once a suitable amount of ferrofluid 321 has been introduced into the chamber 309, the chamber 309 may undergo sealing of the introduction port 335A and the escape port 335B. Sealing may be achieved by readily reversible techniques to allow subsequent introduction of ferrofluid 321 and/or extraction of ferrofluid 321 if desired. Alternatively, the ports 335 may be sealed by brazing, soldering, or other suitable sealing techniques.

In some embodiments, a ferrofluid supply system 336 may be included. The ferrofluid supply system 336 may include suitable components to alter (e.g., increase or decrease) an amount of ferrofluid 321 present in the chamber 309. For simplicity, examples of components of the ferrofluid supply system 336 are shown relative to the second chamber 309B but may be implemented additionally or alternatively relative to the first chamber 309A and/or any arrangement of one or more chambers 309.

The ferrofluid supply system 336 is shown with a reservoir 338, pump 340, a conduit 342, and a valve 344, although fewer, more, or different combinations of any of these and/or other components may be utilized. The reservoir 338 may be sized and arranged to contain ferrofluid 321 separately from the chamber 309. Suitable structure may be included for transferring ferrofluid 321 between the reservoir 338 and the chamber 309. For example, the conduit 342 may provide a path between the reservoir 338 and the chamber 309. The pump 340 may drive ferrofluid 321 from the reservoir 338 into the chamber 309 to increase an amount of ferrofluid 321 in the chamber 309 and/or may drive ferrofluid 321 from the chamber 309 into the reservoir 338 to decrease an amount of ferrofluid 321 in the chamber 309. Additionally or alternatively, the valve 344 may be suitably positioned to block, allow, or otherwise control flow of ferrofluid 321 relative the reservoir 338 and/or the chamber 309. In some embodiments, one or more magnetic field emitters 325 in the set 324 may be operable to drive ferrofluid 321 relative to the chamber 309 and/or reservoir 338 in lieu of and/or as a supplement to the pump 340 and/or the valve 344.

The valve 344 is shown at an end of the conduit 342 and along a boundary of the chamber 309 (e.g., in a location that may be suitable for blocking inadvertent passage of ferrofluid 321 across a boundary of the chamber 309), although any suitable location for controlling flow relative the reservoir 338 and/or the chamber 309 may be utilized. In some embodiments, the conduit 342 or other structure of the ferrofluid supply system 336 may be coupled with an inlet or outlet previously used for initially charging the chamber 309 with ferrofluid 321 (such as the introduction port 335A and/or the escape port 335B).

Differing levels or amounts of ferrofluid 321 may be useful for addressing different conditions. Ferrofluid 321 may be provided in suitable quantity to occupy between 25% and 75% (or other amount or range) relative to a total volume of the chamber 309, for example. Generally, including the ferrofluid supply system 336 may facilitate changing how much ferrofluid 321 (e.g., by total quantity or volumetric ratio) is present in the chamber 309 to accommodate different situations. Reducing an amount of ferrofluid 321 in the reservoir 338 may increase an amount of ferrofluid 321 in the chamber 309 or vice versa. As an illustrative example shown in FIG. 3, changing between the first configuration 303A to the second configuration 303B (as depicted by arrow 329) may include some ferrofluid 321 that was in the reservoir 338 in the first configuration 303A being moved into the chamber 309 in the second configuration 303B, such as to form a block 346 of ferrofluid 321 in the chamber 309. Block 346 also further illustrates by way of example that ferrofluid 321 may be arranged to occupy any area of any desired shape in use.

FIG. 4 illustrates a perspective view of the system 301 implemented relative to other components, such as within a computing system (an example of the computing system 110). For example, the system 301 may include components suitable for including servers, routers, network switches, or other network computing devices.

The system 301 in FIG. 4 is shown with a chassis 337. The chassis 337 may be formed of sheet-metal or any other suitable structure. In some examples, the chassis 303 may be slidable in and/or out of a rack, such as a server rack.

The chassis 337 can include a board 339. The board 339 may correspond to a motherboard and/or other suitable board for receiving and/or interfacing with other elements of the system 301. The board 339 may define at least one socket zone 341, for example. FIG. 4 shows a first socket zone 341A and second socket zone 341B, although any number of one, two, or more socket zones 341 may be utilized. As an illustrative example, the system 301 may be or may correspond to a two-socket server, although features of system 301 may be implemented in three-socket, four-socket, or n-socket varieties of servers or other computing devices.

Each socket zone 341 may correspond to a region in which a heat-generating component 343 may be situated and/or installed in use. For example, although each socket zone 341 is shown with two heat-generating components 343, any suitable combination of one, two, or other numbers may be utilized. In some embodiments, the heat-generating component 343 can include one or more thermo-couple sensors 410. The one or more thermo-couple sensors 410 can be distributed at different locations to measure temperature at respective locations of the heat-generating component 343. In some embodiments, the thermo-couples 410 can send real-time temperature data to the trained machine learning model 130 to generate thermal maps associated with the heat generating components 343 to effectively manage the cooling of the heat-generating component 343.

In various embodiments, the heat-generating components 343 may correspond to integrated circuits (including chips or dice), or other heat-generating components. Non-limiting examples include a processor (an example of the processor 112 in FIG. 1), an input/output (I/O) chip, a baseboard management controller, a chip, a die, a card (e.g., which may include a printed circuit board various that bears other components), a voltage regulator, a hot swap control, an inductor, a resistor, or a capacitor). Other non-limiting examples may include a Field Programmable Gate Array (FPGA), a Complex Programmable Logic Device (CPLD), and a System-on-a-Chip (SoC). Each heat-generating component 343 may include one or more subcomponents that generate heat. In some examples, the heat-generating components 343 may include a first processor and a second processor, although the heat-generating components 343 may be of similar or different types of components relative to each other.

A heat dissipation system 345 may be included relative to the heat-generating components 343. The heat dissipation system 345 may include one or more instances of the cooling plate 305 described with respect to FIG. 3. Although two instances of the heat dissipation system 345 are shown in FIG. 4 (e.g. with one installed in the rightward portion of FIG. 4 and one shown in an upwardly exploded position to show components thereunder at left in FIG. 4), any number of subcomponents and/or collections of components of the heat dissipating system 345 may be implemented in use.

Other components may be included in the system 301, such as fans 347. Elements of the fans 347 or other elements of the heat dissipation system 345 may be controlled independently and/or collectively within the system 301.

FIG. 5 illustrates a series of thermal images or maps representing examples of heat distributions that may occur on or more of the heat-generating components 343. In some embodiments, the thermal maps can be generated by a thermal imaging camera to collect training data (e.g., maps 207) or to provide real-time temperature information to a trained model (e.g., 13). In some embodiments, the thermal maps (e.g., maps 131, 131′ in FIG. 1) can be model-generated during operation of the computing system (e.g., 110). The thermal maps may correspond to different modes 500a, 500b, 500c, 500d, and 500e of operation of the heat-generating component 343, for example. The thermal maps may correspond to heat maps, e.g., which may utilize different intensities of visual indicia to represent different levels of heat in operation. For example, the scale at right in FIG. 5 presents a scale differentiated by density of stippling, where higher density of stippling may correspond to higher temperature.

Heat may be distributed unevenly within and/or between each of the modes 500a-e. For example, heat may be distributed in higher concentrations at and/or around hotspots 502a-e that may be present in each of the modes 500a-e. A hotspot 502 may emerge in a different location with respect to a heat-generating component 343 based on a type of process being performed by the heat-generating component 343 in a given mode 500a-e. For example, different types of processes may involve subcomponents located in different regions of the heat-generating component 343 and may thereby generate greater amounts of heat in different regions of the heat-generating component 343 during different modes 500a-e. As an illustrative example, mode 500a may correspond to a processor executing a large language model or other artificial intelligence (AI) program that primarily makes use of a lower portion of the heat-generating component 343, whereas mode 500b may be a different processor executing a database application that primarily makes use of an upper portion of the same or a different heat-generating component 343. Accordingly, the hotspots 502a and 502b may correspond to physical locations on the heat-generating component 343 that may be generating the most heat and/or may have the highest temperatures.

To address, mitigate, and/or prevent a hotspot 502, coolant flow may be focused relative to the hotspot 502. For example, with respect to features identified in FIG. 5, the system 301 can magnetically manipulate the ferrofluid 321 to adjust a physical characteristic (e.g., location, size, shape, and/or other physical characteristic) of one or more guides 323 to alter a coolant flow profile. To avoid obscuring other features in FIG. 5, dashed lines are utilized to show some generalized examples of different forms of layouts that may be implemented relative to hotspots 502a-e. The dashed lines may represent channel boundaries 504a-e, which may correspond to guides 323 and/or ferrofluid 321 referenced in FIG. 3, for example. The depicted channel boundaries 504a-e may correspond to a set of one or more largest channels implemented in a given instance, and other smaller channels (e.g., similar to in FIG. 3) may be implemented supplementally even though omitted from view in FIG. 5 for clarity or may be omitted altogether depending on flow profiles desired. In some examples, portions or all of spaces outside channel boundaries 504a-e of the largest channel implemented may be partially or completely occupied by ferrofluid 321 in use.

Generally, channel boundaries 504a-e may be respectively implemented in suitable locations, sizes, and/or shapes to impact coolant flow over and/or near the hotspots 502a-e to enhance cooling provided at and/or near the hotspot 502. Although FIG. 5 for simplicity primarily shows channel boundaries 504a-e arranged to define channels that pass over hotspots 502a-e, channels additionally or alternatively may be arranged over other areas or zones. For example, channels may be arranged to control flow so that relatively higher flow (and thus greater cooling) is provided along hotspots 502a-e (or other areas that produce a relatively higher thermal load) and so that relatively lower flow (and thus lesser cooling) passes along different areas that produce a relatively lower thermal load, e.g., such that high cooling is prioritized to zones with high thermal load and commensurate lower cooling is supplied to areas with lower demand for cooling.

Thus, the thermal maps in FIG. 5 may correspond to an illustrative example that includes a processor, chip, or other heat-generating component that may have a plurality of zones that include at least a first zone (e.g., at and/or around hotspot 502a) and a second zone (e.g., at and/or around hotspot 502b) that exhibit different heat-producing characteristics during different modes of operation (e.g., modes 500a and 500b) of the chip processor, chip, or other heat-generating component. Ferrofluid may be arranged in different arrangements, such as those depicted by channel boundaries 504a and 504b. For example, the ferrofluid in the first arrangement may be arranged to form a first set of walls (e.g., channel boundaries 504a) defining a first set of coolant flow paths through the coolant chamber that facilitate a greater amount of coolant flow along the first zone (e.g., at and/or around a location of hotspot 502a) than along the second zone (e.g., at and/or around a location that may later have hotspot 502b). Continuing this example, the ferrofluid in the second arrangement may be arranged to form a different, second set of walls (e.g., channel boundaries 504b) defining a different, second set of coolant flow paths through the coolant chamber that facilitate a greater amount of coolant flow along the second zone (e.g., at and/or around a location of hotspot 502b) than along the first zone (e.g., at and/or around a location that may have previously included hotspot 502b). Leveraging this capability of the ferrofluid, one or more magnetic field emitters 325 (e.g., FIG. 3) may be operable to alter placement of the ferrofluid within the coolant chamber to shift between the first arrangement and the second arrangement so as to arrange the ferrofluid in the first arrangement (e.g., along channel boundaries 504a) to facilitate the greater amount of coolant flow along the first zone (e.g., at or along the hotspot 502a) when the processor, chip, or other heat-generating component is in the first mode (e.g., mode 500a) having the higher heat load in the first zone and so as to arrange the ferrofluid in the second arrangement (e.g., along channel boundaries 504b) to facilitate the greater amount of coolant flow along the second zone (e.g., at or along the hotspot 502b) when the processor, chip, or other heat-generating component is in the second mode (e.g., mode 500b) having the higher heat load in the second zone.

Any suitable form factor may be utilized. Channel boundaries 504a and 504d show examples of straight edges. Where channel boundaries 504a show an example of forming a single large channel across the hotspot 502a, the channel boundaries 504d show an example of forming a central channel and multiple peripheral channels. Channel boundaries 504b,504c, and 504e show examples with curved or otherwise non-straight edges. In some embodiments, curved edges (such as channel boundaries 504b and/or 504c) may be curved toward one another or otherwise suitably arranged to form a nozzle shape, e.g., which may include a narrowing restriction that operates to accelerate fluid flow passing through the restriction. In this manner, the channels may be utilized to increase speed of flow at a target location. Flaring out from the restriction may be included on both sides (such as with channel boundaries 504b) or on a single side (such as with channel boundaries 504c). Channel boundaries 504e show an example in which flow is modulated to flow across multiple hot spots 502e. Multiple hotspots may occur in arrangements that include a Field Programmable Gate Arrays (FPGA), a Complex Programmable Logic Device (CPLD), a System-on-a-Chip (SoC), and/or in other arrangements with multiple types and/or zones of heat-generating components, for example. Overall, any simple or complex flow geometry may be implemented with the ferrofluid 321, including geometries to facilitate and/or direct flow in left and/or rightward directions, in forward and/or backward directions, in up and/or down directions, in diagonal directions, in spiral directions, around and/or along an island and/or edge formed of ferrofluid 321, and/or in other flow arrangements.

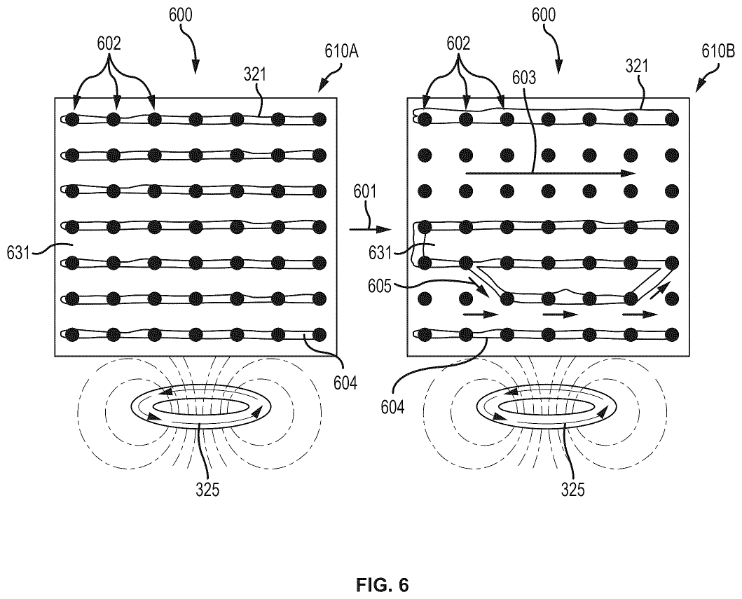

FIG. 6 illustrates a series of fixed anchors 602 that can receive ferrofluid 321 according to certain aspects of the present disclosure. The fixed anchors 602 may be implemented in a coolant chamber 600, which may be an example of the coolant chamber 309. The fixed anchors 602 may be separated by gaps that can be filled or vacated by the ferrofluid 321 to adjust arrangement of coolant flow path boundaries 604 (which may correspond to guides 323, e.g., FIG. 3). The fixed anchors 602 are depicted as cylindrical protrusions but may correspond to projections of square, rectangular, elongate, or any other suitable form factor. The fixed anchors 602 may extend and/or span a full or partial height of the coolant chamber 600 (e.g., in a direction into or out of the page of the view of FIG. 6). The fixed anchors 602 can be fixed in a predetermined plan within the coolant chamber 600 (e.g., a grid-like plan, a repeating plan, or a plan that includes portions that are non-symmetric and/or non-repeating relative to other portions). The fixed anchors 602 may receive ferrofluid 321 such that the fixed anchors 602 and the ferrofluid 321 together define coolant flow path boundaries 604 within the coolant chamber 600. For example, the ferrofluid 321 may be arranged to extend laterally between any pair of respective sequentially adjacent fixed anchors 602 and/or vertically (e.g., above and/or below, such as in a direction into or out of the page of the view of FIG. 6) and/or horizontally (e.g., laterally, such as in a direction in a plane of the page of the view of FIG. 6) relative to any individual fixe anchor 602.

A magnetic field may be applied to the coolant chamber 600 (e.g., via one or more magnetic field emitters 325) such that the ferrofluid 321 relocates among differing arrangements. Relocating the ferrofluid 321 from the first configuration 610A to the second configuration 610B (such as illustrated by arrow 601) may create different coolant flow paths and may increase or alter an amount of cooling supplied in a location of the coolant chamber 600. For example, the ferrofluid 321 may adhere to the fixed anchors 602 in a first configuration 610A to form six even coolant flow paths and may adhere to the fixed anchors 602 in a second configuration 610B such that the ferrofluid 321 and fixed anchors 602 form two uneven current flow paths. As a result, a relatively higher amount of coolant flow may be provided along the expanded upper channel (such as depicted by arrow 603) while a relatively smaller amount of coolant flow may be provided along the lower channel (such as depicted by arrows 605). Flow through the lower channel may be accelerated by the nozzle shape imparted (such as depicted by arrows 605), for example. Flow may be modulated within the coolant chamber 600 by altering a channel size to affect an amount of flow and/or by adjusting a shape to affect a speed of flow.

In some examples, the fixed anchors 602 may have certain electrostatic properties that enable the ferrofluid to adhere to the fixed anchors 602. For example, an electrical attraction between the fixed anchors 602 and the ferrofluid may enable the creation of more predictably shaped coolant flow path boundaries 604 and may thereby provide additional control of a size, location, and/or shape associated with each coolant flow path. More generally, the fixed anchors 602 may be configured to provide at least a mild attraction to the ferrofluid 321 (such as by including material with magnetic properties or otherwise including a coating to attract material in the ferrofluid 321), which may cause the ferrofluid 321 to be predisposed to adhere to, couple with, or otherwise remain in a predictable arrangement relative the fixed anchors 602 absent magnetic fields in suitable strength and/or arrangement to overcome the effect of the fixed anchor and re-arrange the ferrofluid 321.

In some embodiments, ferrofluid 321 initially situated among one set of fixed anchors 602 may be relocated to be aggregated among other fixed anchors 602. For example, in FIG. 5, the ferrofluid 321 in the uppermost row in the second configuration 610B is depicted thicker than in the first configuration 610A, which may correspond to aggregating the ferrofluid 321 from the second and third row during the transition. In some embodiments, ferrofluid 321 may be moved to block or unblock a channel. As an example in FIG. 5, the left end of the channel 631 is shown blocked by ferrofluid 321 in the second configuration 610B and unblocked by the ferrofluid in the first configuration 610A. The channel 631 may be closed by moving from the first configuration 610A to the second configuration 610B and/or may be opened by moving to the first configuration 610A from the second configuration 610B. Although blocking, unblocking, closing, and opening are discussed with respect to the coolant chamber 600 with fixed anchors 602 in FIG. 6, such manipulations may be performed in the chamber 309 of FIG. 3 or other chamber in which fixed anchors 602 are not present.

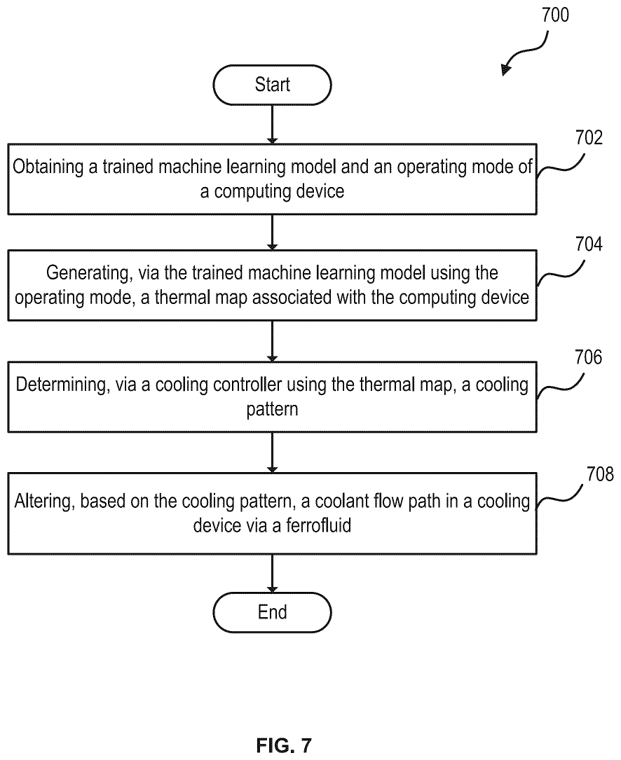

FIG. 7 is a flow chart depicting a process that may be performed with respect to a coolant system e.g., of FIGS. 1 and 3. Some or all of the process 700 (or any other processes described herein, or variations, and/or combinations thereof) may be performed under the control of one or more computer systems configured with executable instructions and may be implemented as code (e.g., executable instructions, one or more computer programs, or one or more applications) executing collectively on one or more processors, by hardware or combinations thereof. The code may be stored on a computer-readable storage medium, for example, in the form of a computer program comprising a plurality of instructions executable by one or more processors. The computer-readable storage medium may be non-transitory.

At operation 702, the process 700 can include obtaining a trained machine learning model and an operating mode of a computing device. For example, as shown in FIG. 1, the trained model 130, and an operating mode 105 of the computing system 110 can be obtained. In some embodiments, the obtaining of the trained machine learning model 130 may include a training process (e.g., see FIG. 2). For example, obtaining the trained model 130 may involve receiving training data associated with the computing device (e.g., 110). In some embodiments, the training data can include (i) one or more operating modes (e.g., 205) of the computing device (e.g., 110) and (ii) a plurality of thermal maps (e.g., 207) associated with each of the operating modes (e.g., 205) of the computing device (e.g., 110). In some embodiments, the training data can further include temperature data from temperature sensors (e.g., thermo-couples 410 in FIG. 4) on the processor (e.g., 110). In another example, the temperature data may be obtained by a thermal imaging camera or other temperature sensors coupled to but located away from the computing device (e.g., 110). A machine learning model (e.g., 210 in FIG. 2) can be trained to generate the thermal map (e.g., 211) by adjusting one or more model parameters (e.g., denoted by a block 215), such as based on a cost function. For example, model parameters can be adjusted to minimize or reduce differences between model-generated thermal maps (e.g., 211) and the plurality of thermal maps (e.g., 207) of the training data.

At operation 704, the process 700 can include generating, via the trained machine learning model using the operating mode, a thermal map associated with the computing device. The thermal map can be predicted temperature variations across the computing device. For example, FIG. 1 illustrates the trained model 130 can generate a thermal map 131 based on the input operating mode 105.

At operation 706, the process 700 can include determining, via a cooling controller using the thermal map, a cooling pattern (e.g., a coolant flow path) to minimize or reduce temperature variations across the computing device. For example, FIG. 1 illustrates the cooling controller 140 configured to receive the thermal map 131 to generate the coolant flow path to reduce or minimize temperature variations across the computing device 150.

At operation 708, the process 700 can include altering, based on the cooling pattern, a coolant flow path in a cooling device via a ferrofluid. In some embodiments, the altering can include creating, based on the cooling pattern, a set of walls in the cooling device via the ferrofluid to direct a coolant along the coolant flow path. In some embodiments, creating of the set of walls can include applying, based on the coolant flow path, a magnetic field via one or more electromagnets to cause the ferrofluid to form a set of walls to create the coolant flow path within the cooling device. For example, the coolant flow path generated by the cooling controller (e.g., 140 in FIG. 1) can be input to the cooling device (e.g., 301 in FIG. 3). The cooling device 301 may include a cooling plate 305 and ferrofluid 321 configured to create walls (e.g., defined by boundaries 504a, 504b in FIG. 5). The walls can be created by applying magnetic field via one or more electromagnets (e.g., 325 in FIG. 6) to the ferrofluid 321. This creates coolant channels (e.g., 631 in FIG. 6) defined by the coolant flow path generated by the cooling controller (e.g., 140).

The method 700 can further include receiving real-time temperature related data from the computing device, and generating, via the trained machine learning model using the real-time temperature related data, an updated thermal map. For example, as shown in FIG. 1, the trained model 130 can receive temperature data from the computing device 110. In some embodiments, the temperature data can be provided by thermo-couples 410 (in FIG. 4) on a computing component (e.g., 343). Based on the real-time temperature data, the trained model 130 can generate an updated thermal map 131′.

In some embodiments, the method 700 can further include generating, via the cooling controller using the updated thermal map, an updated coolant flow path to minimize or reduce updated temperature variations of the computing device. Based on the updated coolant flow path, the magnetic field can be altered via the one or more electromagnets to cause the ferrofluid to modify the set of walls to direct the coolant along the updated coolant flow path within the cooling device. For example, the cooling controller (e.g., 140 of FIG. 1) can update the coolant path based on the thermal map (e.g., 131′ in FIG. 1). In some embodiments, based on the updated coolant path, the magnetic field can be altered by the one or more electromagnets (e.g., 325 in FIG. 3) to cause ferrofluid (e.g., 321) to form a modified set of walls (e.g., as shown in FIG. 6).

Based on the disclosure and teachings provided herein, a person of ordinary skill in the art will appreciate other ways and/or methods to implement the various embodiments. The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is intended to be understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Various embodiments of this disclosure are described herein, including the best mode known to the inventors for carrying out the disclosure. Variations of those embodiments may become apparent to those of ordinary skill in the art upon reading the foregoing description. The inventors expect skilled artisans to employ such variations as appropriate and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

What is claimed is:

1. A liquid-cooled computing system comprising:
a processor; and
a cooling system configured to dissipate heat from the processor, the cooling system comprising:
a trained machine learning model configured to generate a thermal map based on an operating mode of the processor, wherein the thermal map identifies a plurality of heat zones having different temperatures across the processor;
a cooling controller configured to plan a coolant flow path based on the thermal map generated by the trained machine learning model, the coolant flow path indicating a coolant path along the plurality of heat zones such that a first heat zone having a higher temperature than a second heat zone is cooled first; and
a cooling device coupled to the processor, the cooling device comprising an amount of ferrofluid configured to create a set of walls based on the coolant flow path to direct a greater amount of coolant flow along the first heat zone having higher temperature than along the second heat zone of the plurality of heat zones.

2. The system of claim 1, wherein the trained machine learning model is further configured to generate an updated thermal map based on a duration of operating time of the processor, and/or temperature related data obtained from the processor.

3. The system of claim 2, wherein the temperature related data comprises at least one of: temperature values obtained from thermo-couples within the processor, or processor states.

4. The system of claim 1, wherein the cooling device further comprises:
a cooling plate assembly positioned over the processor, the cooling plate assembly comprising a body defining a coolant chamber having a coolant inlet and a coolant outlet;
an amount of ferrofluid within the coolant chamber, wherein the ferrofluid is arrangeable to form a set of walls defining the coolant flow path through the coolant chamber; and
a magnet set comprising one or more electromagnets coupled with the body, the magnet set operable to alter placement of the ferrofluid within the coolant chamber to create the set of walls to facilitate a greater amount of coolant flow along heat zones having higher temperatures relative to other heat zones of the plurality of heat zones.

5. The system of claim 4, wherein the cooling device further comprises a set of fixed anchors fixed in a predetermined plan within the coolant chamber and configured to receive the ferrofluid such that the fixed anchors and the ferrofluid together define coolant flow path boundaries within the coolant chamber, the coolant flow path boundaries defining the coolant flow path.

6. The system of claim 4, wherein the magnet set includes electromagnets positioned on differing sides of the coolant chamber to enable interaction among differing magnetic fields to control arrangement of the ferrofluid.

7. A cooling system configured to generate dynamic coolant flow paths, the system comprising:
a trained machine learning model configured to generate and update a thermal map based on changing operating conditions of a computing device, the thermal map indicating thermal variations across the computing device;
a cooling controller configured to generate coolant circulation characteristics based on the thermal map or an updated thermal map received from the trained machine learning model, wherein the coolant circulation characteristics along the computing device minimizes or reduces the thermal variations across the computing device; and
a cooling device coupled to the computing device and configured to create coolant flow across the computing device based on the coolant circulation characteristics.

8. The cooling system of claim 7, wherein the cooling device comprises:
a cooling plate formed on the computing device or couplable with the computing device;
an amount of ferrofluid configured to form rearrangeable set of walls based on the coolant circulation characteristics, wherein the coolant circulation characteristics comprises a coolant flow path along different heat zones associated with the thermal map of the computing device; and
a magnet set comprising one or more electromagnets coupled with the cooling plate, the magnet set operable to alter placement of the ferrofluid to create the set of walls.

9. The cooling system of claim 8, wherein the cooling device further comprises a set of fixed anchors fixed in a predetermined plan within the cooling plate; and configured to receive the ferrofluid such that the fixed anchors and the ferrofluid together define coolant flow path boundaries within the cooling plate.

10. The cooling system of claim 7, wherein the cooling device comprises:
a fan configured to direct an air flow and an amount of air over the computing device, wherein the coolant circulation characteristics comprises at least one of an air flow direction along different heat zones, or a fan speed to direct the amount of air along different zones associated with the thermal map of the computing device.

11. The cooling system of claim 7, wherein the coolant characteristics comprises at least one of a coolant flow path, a coolant type, a coolant amount, or a coolant flow rate.

12. The cooling system of claim 7, wherein the trained machine learning model is further configured to generate the updated thermal map based on a duration of operating time of a processor, and/or temperature related data obtained from the processor.

13. The cooling system of claim 12, wherein the temperature related data comprises at least one of: temperature values obtained from thermo-couples within the processor, or processor states.

14. The cooling system of claim 12, wherein the trained machine learning model is at least one of: a convolutional neural network, or a regression model.

15. The cooling system of claim 7, wherein:
the trained machine learning model is further configured to receive temperature feedback associated with the computing device, and generate an updated thermal map based on the temperature feedback;
the cooling controller is configured to determine updated coolant circulation characteristics based on the updated thermal map; and
the cooling device is configured to change coolant flow based on the coolant circulation characteristics.

16. A method of cooling a computing device, the method comprising:
obtaining a trained machine learning model and an operating mode of a computing device;
generating, via the trained machine learning model using the operating mode, a thermal map associated with the computing device, the thermal map indicating temperature variations across the computing device;
determining, via a cooling controller using the thermal map, a coolant flow path to minimize or reduce temperature variations across the computing device; and
creating, based on the coolant flow path, a set of walls in a cooling device via a ferrofluid to direct a coolant along the coolant flow path.

17. The method of claim 16, wherein the obtaining of the trained machine learning model comprises:
receiving training data comprising: (i) one or more operating modes of the computing device, (ii) a plurality of thermal maps associated with each of the operating modes of the computing device, and (iii) temperature data from thermo-couples on the computing device; and
training a machine learning model to generate the thermal map by adjusting one or more model parameters based on a cost function, wherein the cost function is configured to minimize differences between model generated thermal maps and the plurality of thermal maps of the training data.

18. The method of claim 16, wherein the creating of the set of walls comprises:
applying, based on the coolant flow path, a magnetic field via one or more electromagnets to cause the ferrofluid to form a set of walls to create the coolant flow path within the cooling device.

19. The method of claim 16, wherein further comprises:
receiving real-time temperature related data from the computing device; and
generating, via the trained machine learning model using the real-time temperature related data, an updated thermal map.

20. The method of claim 19, further comprising:
generating, via the cooling controller using the updated thermal map, an updated coolant flow path to minimize or reduce updated temperature variations of the computing device; and
altering, based on the updated coolant flow path, a magnetic field via the one or more electromagnets to cause the ferrofluid to modify the set of walls to direct the coolant along the updated coolant flow path within the cooling device.
